(19) United States
(12) Patent Application Publication
(10) Pub. No.: US 2025/0105216 A1
(43) Pub. Date: Mar. 27, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Jing Cheng LIN, Suwon-si (KR); Youngkun Jee, Suwon-si (KR); Jihwan Suh, Suwon-si (KR); Hyunchul Jung, Suwon-si (KR)

(73) Assignee: SAMSUNG ELECTRONICS CO., LTD., Suwon-si (KR)

(21) Appl. No.: 18/808,787

(22) Filed: Aug. 19, 2024

(30) Foreign Application Priority Data
Sep. 25, 2023 (KR) 10-2023-0128481

(51) Int. Cl. H01L 25/065; H01L 23/00

(52) U.S. Cl. CPC H01L 25/0657; H01L 24/08; H01L 2224/08145; H01L 2224/085; H01L 2225/06524

(57) ABSTRACT

Provided is a semiconductor package and method of manufacturing same, the semiconductor package including: a first semiconductor chip; a chip stacked structure on the first semiconductor chip, the chip stacked structure including a plurality of second semiconductor chips; a third semiconductor chip on the chip stacked structure; an adhesive layer between the chip stacked structure and the third semiconductor chip; and a first pad pattern on a lower surface of the third semiconductor chip, wherein the adhesive layer surrounds the first pad pattern and the adhesive layer is between the first pad pattern and the chip stacked structure.

### CROSS-REFERENCE TO RELATED APPLICATION

This application is based on and claims priority to Korean Patent Application No. 10-2023-0128481, filed on Sep. 25, 2023, in the Korean Intellectual Property office, the disclosure of which is incorporated by reference herein in its entirety.

### BACKGROUND

### 1. Field

The disclosure relates to a semiconductor package and a method of manufacturing the semiconductor package. More particularly, the disclosure relates to a semiconductor package including stacked semiconductor chips, and a method of manufacturing the semiconductor package.

### 2. Description of Related Art

Electronic devices have become more compact and lighter due to the development of the electronics industry and the demand of users. As electronic devices become more compact and lighter, semiconductor packages included in electronic devices are also becoming more compact and lighter, and in addition, semiconductor packages require high integration and high speed. According to this demand, semiconductor packages including stacked semiconductor chips have been developed.

### SUMMARY

Provided are a semiconductor package having structural reliability improvement and a method of manufacturing the semiconductor package.

According to an aspect of the disclosure, a semiconductor package includes: a first semiconductor chip; a chip stacked structure on the first semiconductor chip, the chip stacked structure including a plurality of second semiconductor chips; a third semiconductor chip on the chip stacked structure; an adhesive layer between the chip stacked structure and the third semiconductor chip; and a first pad pattern on a lower surface of the third semiconductor chip, wherein the adhesive layer surrounds the first pad pattern and the adhesive layer is between the first pad pattern and the chip stacked structure.

According to an aspect of the disclosure, a semiconductor package includes: a package substrate; an interposer substrate on the package substrate; a sub semiconductor package on the interposer substrate; and a semiconductor chip on the interposer substrate, wherein the semiconductor chip is spaced apart from the sub semiconductor package in a horizontal direction, wherein the sub semiconductor package includes: a first semiconductor chip; a chip stacked structure on the first semiconductor chip, the chip stacked structure including a plurality of second semiconductor chips; a third semiconductor chip on the chip stacked structure; an adhesive layer between the chip stacked structure and the third semiconductor chip; and a first pad pattern on a lower surface of the third semiconductor chip, and wherein the adhesive layer surrounds the first pad pattern and the adhesive layer is between the first pad pattern and the chip stacked structure.

According to an aspect of the disclosure, a semiconductor package includes: a first semiconductor chip; a chip stacked structure on the first semiconductor chip, the chip stacked structure including a plurality of second semiconductor chips bonded to each other by metal-metal bonding; a third semiconductor chip on the chip stacked structure, the third semiconductor chip including a dummy chip; an adhesive layer between the chip stacked structure and the third semiconductor chip, wherein the adhesive layer protrudes from a side surface of the third semiconductor chip to an outside; a molding layer covering the side surface of the third semiconductor chip and a side surface of each of the chip stacked structure and the adhesive layer; and a first pad pattern on a lower surface of the third semiconductor chip, wherein an upper surface of an uppermost second semiconductor chip among the plurality of second semiconductor chips includes a depression void filled by the adhesive layer, wherein the adhesive layer surrounds the first pad pattern and the adhesive layer is between the first pad pattern and the chip stacked structure, and wherein the first pad pattern overlaps the chip stacked structure in a vertical direction.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a cross-sectional view of a semiconductor package according to an embodiment;

FIG. 2 is an enlarged view of region EX1 in FIG. 1;

FIG. 3 is an enlarged view of a region corresponding to region EX1 in FIG. 1;

FIG. 4 is a cross-sectional view of a semiconductor package according to an embodiment;

FIG. 5 is an enlarged view of region EX2 in FIG. 4;

FIG. 6 is an enlarged view of a region corresponding to region EX2 in FIG. 4;

FIG. 7 is an enlarged view of a region corresponding to region EX2 in FIG. 4;

FIG. 8 is a cross-sectional view of a semiconductor package according to an embodiment;

FIG. 9 is an enlarged view of a region corresponding to region EX3 in FIG. 8;

FIG. 10 is an enlarged view of a region corresponding to region EX3 in FIG. 8;

FIGS. 11, 12A, 12B, 13A, 13B, and 14 are cross-sectional views for describing a method of manufacturing a semiconductor package, according to one or more embodiments; and

FIG. 15 is a cross-sectional view of a semiconductor package according to an embodiment.

### DETAILED DESCRIPTION

Hereinafter, embodiments of the disclosure are described in detail with reference to the accompanying drawings. Identical reference numerals are used for the same constituent elements in the drawings, and duplicate descriptions thereof are omitted.

In the following description, like reference numerals refer to like elements throughout the specification. Well-known functions or constructions are not described in detail since they would obscure the one or more exemplar embodiments with unnecessary detail. As used herein, a plurality of “units”, “modules”, “members”, and “blocks” may be implemented as a single component, and a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

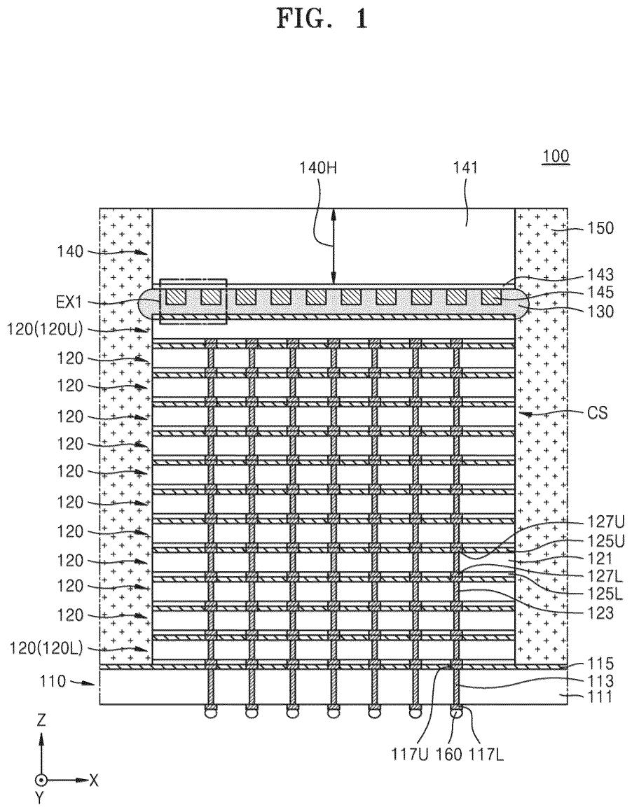

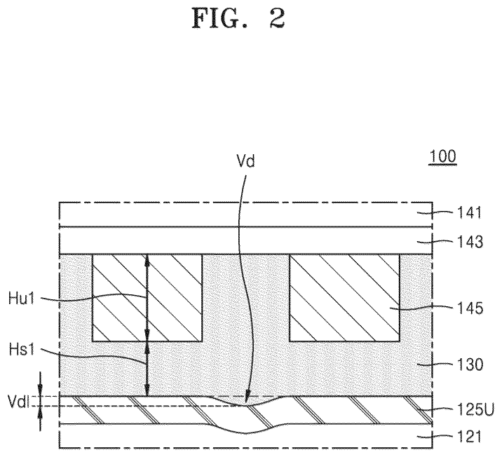

FIG. 1A is a cross-sectional view of a semiconductor package 100 according to an embodiment. FIG. 2 is an enlarged view of region EX1 in FIG. 1.

Referring to FIGS. 1 and 2, the semiconductor package 100 may include a first semiconductor chip 110, a chip stacked structure CS including a plurality of second semiconductor chips 120, and a third semiconductor chip 140.

The first semiconductor chip 110 may include, for example, a buffer chip for controlling the plurality of second semiconductor chips 120 included in the chip stacked structure CS. For example, each of the plurality of second semiconductor chips 120 may include a high bandwidth memory (HBM) dynamic random access memory (RAM) (DRAM) chip, and the first semiconductor chip 110 may include a buffer chip for controlling the plurality of second semiconductor chips 120 (i.e., the HBM DRAM chips). The first semiconductor chip 110 may include, for example, a test logic circuit, such as a serial-parallel conversion circuit, a design for test (DFT) circuit, a joint test action group (JTAG) circuit, a memory built-in self-test (MBIST) circuit, and a signal interface circuit such as a physical layer (PHY) circuit.

In one or more embodiments, a horizontal area of the first semiconductor chip 110 may be greater than a horizontal area of each of the chip stacked structure CS and the third semiconductor chip 140. For the purposes of this disclosure, “horizontal area” refers to an area in the XY plane (see, e.g., FIG. 1, where planar/directional indicators are included).

The first semiconductor chip 110 may include a first semiconductor substrate 111, a plurality of first through electrodes 113, a first upper insulating layer 115, a plurality of first lower pads 117L, and a plurality of first upper pads 117U.

The first semiconductor substrate 111 may include, for example, a semiconductor element, such as Si and Ge, and at least one chemical semiconductor of SiGe, SiC, GaAs, InAs, and InP. The first semiconductor substrate 111 may include a conductive region, for example, a well doped with impurities or a structure doped with impurities. The first semiconductor substrate 111 may have various element isolation structures such as a shallow trench isolation (STI) structure.

The first semiconductor substrate 111 may include an active surface and an inactive surface opposite to the active surface. Various types of a plurality of individual devices may be formed on the active surface. The plurality of individual devices may include, for example, a metal-oxide semiconductor field effect transistor (MOSFET) such as a complementary metal-oxide semiconductor (CMOS) transistor, an image sensor, such as system large scale integration (LSI) and a CMOS imaging sensor (CIS), a micro-electro-mechanical system (MEMS), an active element, a passive element, etc. The plurality of individual devices may be electrically connected to the conductive region of the first semiconductor substrate 111. Each of the plurality of individual devices may be mutually and electrically insulated from other adjacent individual devices by an insulating layer.

The first semiconductor substrate 111 may further include a first wiring layer arranged on the active surface. The first wiring layer may be electrically connected to the plurality of first through electrodes 113. The first wiring layer may include, for example, a first front end of line (FEOL) layer or a back end of line (BEOL) layer, but the disclosure is not limited thereto.

The plurality of first through electrodes 113 may penetrate the first semiconductor substrate 111 to be connected in a vertical direction (Z direction). Each of the plurality of first through electrodes 113 may be apart from each other horizontally. The first through electrode 113 may electrically connect the first upper pad 117U to the first lower pad 117L. The first through electrode 113 may overlap the first upper pad 117U and the first lower pad 117L in the vertical direction (Z direction).

The first upper insulating layer 115 may be arranged on an upper surface of the first semiconductor substrate 111. The first upper insulating layer 115 may cover the upper surface of the first semiconductor substrate 111. The first upper insulating layer 115 may include, for example, oxide, nitride, or a combination thereof.

The plurality of first upper pads 117U may be arranged on the upper surface of the first semiconductor substrate 111. The first upper pads 117U may penetrate the first upper insulating layer 115 in the vertical direction (Z direction). Side surfaces of the first upper pads 117U may be covered by the first upper insulating layer 115. The plurality of first lower pads 117L may be arranged under a lower surface of the first semiconductor substrate 111. The first upper pad 117U and the first lower pad 117L may overlap each other in the vertical direction (Z direction). Each of the first upper pad 117U and the first lower pad 117L may include, for example, Cu.

A plurality of first connection terminals 160 may be respectively arranged under lower surfaces of the plurality of first lower pads 117L. Each of the plurality of first connection terminals 160 may include, for example, a solder ball or a solder bump. Each of the plurality of first connection terminals 160 may include a solder material. The solder material may include, for example, tin (Sn), indium (In), bismuth (Bi), antimony (Sb), copper (Cu), silver (Ag), zinc (Zn), lead (Pb), and/or an alloy thereof. The first semiconductor chip 110 may be electrically connected to an external device via the plurality of first connection terminals 160.

The chip stacked structure CS may be arranged on the first semiconductor chip 110. The chip stacked structure CS may include the plurality of second semiconductor chips 120 stacked on the upper surface of the first semiconductor chip 110 in the vertical direction (Z direction). In one or more embodiments, the plurality of second semiconductor chips 120 may include a volatile memory semiconductor chip, such as dynamic random access memory (RAM) (DRAM) and static RAM (SRAM), or a non-volatile memory chip, such as phase-change RAM (PRAM), magneto-resistive RAM (MRAM), ferroelectric RAM (FeRAM), and resistive RAM (RRAM). For example, each of the plurality of second semiconductor chips 120 may include a HBM DRAM chip constituting HBM.

As illustrated in FIG. 1, the chip stacked structure CS may include twelve second semiconductor chips 120 stacked in the vertical direction (Z direction), but the disclosure is not limited thereto. For example, the chip stacked structure CS may also include a multiple of four, for example, eight or sixteen second semiconductor chips 120.

For convenience of explanation below, the second semiconductor chip 120 at the lowermost end of the plurality of second semiconductor chips 120 may be referred to as a lowermost second semiconductor chip 120L, and the second semiconductor chip 120 at the uppermost end of the plurality of second semiconductor chips 120 may be referred to as an uppermost second semiconductor chip 120U.

Each of the plurality of second semiconductor chips 120, except for the uppermost second semiconductor chip 120U, may include a second semiconductor substrate 121, a plurality of second through electrodes 123, a second upper insulating layer 125U, a second lower insulating layer 125L, a plurality of second upper pads 127U, and a plurality of second lower pads 127L. The uppermost second semiconductor chip 120U may include the second semiconductor substrate 121, the second upper insulating layer 125U, the second lower insulating layer 125L, and the plurality of second lower pads 127L. In other words, the uppermost second semiconductor chip 120U, unlike other second semiconductor chips 120, may not include the plurality of second through electrodes 123 and the plurality of second upper pads 127U.

The second semiconductor substrate 121 may include a material substantially the same as or similar to the first semiconductor substrate 111. For example, the second semiconductor substrate 121 may include Si. The second semiconductor substrate 121 may have a structure substantially the same as or similar to the first semiconductor substrate 111. For example, the second semiconductor substrate 121 may have an active surface and an inactive surface opposite to the active surface, and various types of individual elements may be formed. In addition, the second semiconductor substrate 121 may be arranged on the active surface, and may further include a second wiring layer electrically connected to the plurality of second through electrodes 123. The second wiring layer may include, for example, a FEOL layer or a BEOL layer.

The plurality of second through electrodes 123 may penetrate the second semiconductor substrate 121 to extend in the vertical direction (Z direction). The plurality of second through electrodes 123 may be apart from each other horizontally. The second through electrode 123 may electrically connect the second upper pad 127U to the second lower pad 127L. The second through electrode 123 may overlap the second upper pad 127U and the second lower pad 127L in the vertical direction (Z direction).

The second upper insulating layer 125U may be arranged on an upper surface of the second semiconductor substrate 121, and the second lower insulating layer 125L may be arranged under a lower surface of the second semiconductor substrate 121. The second upper insulating layer 125U may cover the upper surface of the second semiconductor substrate 121, the second lower insulating layer 125L may cover the lower surface of the second semiconductor substrate 121. Each of the second upper insulating layer 125U and the second lower insulating layer 125L may include a material substantially the same as or similar to the first upper insulating layer 115.

The plurality of second upper pads 127U may be arranged on the upper surface of the second semiconductor substrate 121. The second upper pad 127U may penetrate the second upper insulating layer 125U in the vertical direction (Z direction). Side surfaces of the second upper pad 127U may be covered by the second upper insulating layer 125U. The plurality of second lower pads 127L may be arranged under the lower surface of the second semiconductor substrate 121. The second lower pad 127L may penetrate the second lower insulating layer 125L in the vertical direction (Z direction). Side surfaces of the second lower pad 127L may be covered by the second lower insulating layer 125L. The second upper pad 127U and the second lower pad 127L may overlap each other in the vertical direction (Z direction). The second upper pad 127U and the second lower pad 127L may include materials substantially the same as or similar to the first upper pad 117U and the first lower pad 117L, respectively.

In one or more embodiments, the uppermost second semiconductor chip 120U may include a depression void Vd on an upper surface thereof. As the plurality of second semiconductor chips 120 are stacked, the depression void Vd may be formed on the upper surface of the uppermost second semiconductor chip 120U to overlap the second wiring layer included in each of the plurality of second semiconductor chips 120 in the vertical direction (Z direction). Due to the depression void Vd, the upper surface of the uppermost second semiconductor chip 120U may have a curved surface not a flat surface. A vertical direction height Vdl of the depression void Vd may be about 0.45 μm.

The chip stacked structure CS may be connected to the first semiconductor chip 110 by using a metal-metal direct bonding. For example, as the second lower pad 127L of the lowermost second semiconductor chip 120L and the first upper pad 117U of the first semiconductor chip 110 contact each other in the vertical direction (Z direction) to be metal-metal direct bonded, the chip stacked structure CS may be connected to the first semiconductor chip 110.

In addition, in the chip stacked structure CS, the plurality of second semiconductor chips 120 may be connected to each other by using the metal-metal direct bonding. For example, as the second upper pad 127U of one second semiconductor chip 120 contacts the second lower pad 127L of another second semiconductor chip 120 arranged on the one second semiconductor chip 120 in the vertical direction (Z direction) to be metal-metal direct bonded, the plurality of second semiconductor chips 120 may be connected to each other.

The third semiconductor chip 140 may be arranged on the chip stacked structure CS. In one or more embodiments, the third semiconductor chip 140 may include a dummy chip. In one or more embodiments, the third semiconductor chip 140 may have a vertical direction height 140H of about 100 μm or more. However, the disclosure is not limited thereto, and the vertical direction height 140H of the third semiconductor chip 140 may vary according to the number of the plurality of second semiconductor chips 120 included in the chip stacked structure CS. In one or more embodiments, the vertical direction height 140H of the third semiconductor chip 140 may be greater than a vertical direction height of each of the first semiconductor chip 110 and the plurality of second semiconductor chips 120. In one or more embodiment, a horizontal area of the third semiconductor chip 140 may be substantially the same as a horizontal area of each of the plurality of second semiconductor chips 120 included in the chip stacked structure CS.

The third semiconductor chip 140 may include a third semiconductor substrate 141 and a third lower insulating layer 143. The third semiconductor substrate 141 may include only a semiconductor material such as Si. The third lower insulating layer 143 may be arranged under a lower surface of the third semiconductor substrate 141. The third lower insulating layer 143 may cover the lower surface of the third semiconductor substrate 141. The third lower insulating layer 143 may include a material substantially the same as or similar to the first upper insulating layer 115.

An adhesive layer 130 may be arranged between the third semiconductor chip 140 and the chip stacked structure CS. A horizontal area of the adhesive layer 130 may be substantially the same as a horizontal area of each of the second semiconductor chips 120 and the third semiconductor chip 140. The adhesive layer 130 may include, for example, a non-conductive film (NCF). The adhesive layer 130 may fill a space between the third semiconductor chip 140 and the chip stacked structure CS. Accordingly, the depression void Vd formed on an upper surface of the uppermost second semiconductor chip 120U may also be filled with the adhesive layer 130. The adhesive layer 130 may protrude from side surfaces of the third semiconductor chip 140 to the outside.

A plurality of pad patterns 145 may be arranged under a lower surface of the third semiconductor chip 140. Each of the plurality of pad patterns 145 may extend from the lower surface of the third semiconductor chip 140 toward the uppermost second semiconductor chip 120U in the vertical direction (Z direction). The plurality of pad patterns 145 may overlap the chip stacked structure CS in the vertical direction (Z direction). Each of the plurality of pad patterns 145 may be surrounded by the adhesive layer 130. For example, side surfaces and a lower surface of each of the plurality of pad patterns 145 may be surrounded by the adhesive layer 130. The plurality of pad patterns 145 may be separated from the uppermost second semiconductor chip 120U with the adhesive layer 130 therebetween in the vertical direction (Z direction). The plurality of pad patterns 145 may function as a heat dissipation path. For example, when the plurality of second semiconductor chips 120 operate, the plurality of pad patterns 145 may function as a path for dissipating heat generated by the plurality of second semiconductor chips 120.

In one or more embodiments, a vertical direction height Hu1 of each of the plurality of pad patterns 145 may be about 3 μm or more and about 4 μm or less. For example, the vertical direction height Hu1 of each of the plurality of pad patterns 145 may be about 3 μm.

In one or more embodiments, a separation distance Hs1 in the vertical direction (Z direction) between each of the plurality of pad patterns 145 and the uppermost second semiconductor chip 120U may be about 2 μm or less. For example, the separation distance Hs1 in the vertical direction (Z direction) between each of the plurality of pad patterns 145 and the uppermost second semiconductor chip 120U may be about 1 μm.

In one or more embodiments, each of the plurality of pad patterns 145 may have a rectangular shape on a cross-section perpendicular to a second horizontal direction (Y direction).

In one or more embodiments, the plurality of pad patterns 145 may be arranged on the entire area of the lower surface of the third semiconductor chip 140. For example, the plurality of pad patterns 145 may be arranged in rows and columns on the entire area of the lower surface of the third semiconductor chip 140 to be spaced apart from each other at regular intervals.

In one or more embodiments, the sum of the area of each of the plurality of pad patterns 145 on a plane perpendicular to the second horizontal direction (Y direction) may be about 5% to about 30% of the area of the third semiconductor chip 140 on a plane perpendicular to the second horizontal direction (Y direction). When the sum of the area of each of the plurality of pad patterns 145 is out of the range described above, the heat dissipation performance of the semiconductor package 100 may be deteriorated.

In one or more embodiments, each of the plurality of pad patterns 145 may include Ni, Cu, or a combination thereof. For example, each of the plurality of pad patterns 145 may include Cu.

A molding layer 150 may be arranged on the first semiconductor chip 110, and may cover side surfaces of the chip stacked structure CS, the adhesive layer 130, and the third semiconductor chip 140. An upper surface of the molding layer 150 may be on the same flat surface as an upper surface of the third semiconductor chip 140 in a horizontal direction. However, the disclosure is not limited thereto, and the molding layer 150 may also cover the upper surface of the third semiconductor chip 140. The molding layer 150 may include, for example, epoxy molding compound (EMC), but the disclosure is not limited thereto.

The semiconductor package 100 according to embodiments may include the adhesive layer 130 bonding the chip stacked structure CS and the third semiconductor chip 140, and may include the plurality of pad patterns 145 separated from the chip stacked structure CS with the adhesive layer 130 therebetween on the lower surface of the third semiconductor chip 140 in the vertical direction (Z direction).

Because the adhesive layer 130 fills a space between the chip stacked structure CS and the third semiconductor chip 140 by using a thermal compression process in a manufacturing process of the semiconductor package 100, the depression void Vd formed on the upper surface of the uppermost second semiconductor chip 120U of the chip stacked structure CS may be filled with the adhesive layer 130. Accordingly, unlike the case in which the chip stacked structure CS and the third semiconductor chip 140 are directly bonded together by using Si—O—Si bonding or the like, without the adhesive layer 130, an occurrence of a void due to the depression void Vd on a bonding interface of the chip stacked structure CS and the third semiconductor chip 140 may be prevented. In addition, the plurality of pad patterns 145 formed under the lower surface of the third semiconductor chip 140 may function as a heat dissipation path. Accordingly, the structural reliability may be improved, and at the same time, the semiconductor package 100 maintaining good heat dissipation performance may be provided.

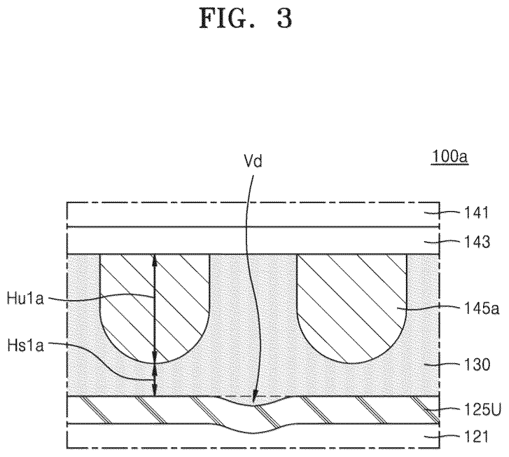

FIG. 3 is an enlarged view of a region corresponding to region EX1 in FIG. 1. FIG. 3 is an enlarged cross-sectional view enlarging a region corresponding to region EX1 in FIG. 1 among cross-sections of a semiconductor package 100a, according to an embodiment. Because components of the semiconductor package 100a illustrated in FIG. 3 are similar to components of the semiconductor package 100 illustrated in FIGS. 1 and 2, differences thereof are mainly described below.

Referring to FIG. 3, the semiconductor package 100a may have substantially the same components as the components of the semiconductor package 100 illustrated in FIGS. 1 and 2, except that the semiconductor package 100a includes a plurality of pad patterns 145a having an inverted dome-shaped cross-section rather than the rectangular cross-section of the plurality of pad patterns 145 illustrated in FIGS. 1 and 2.

Each of the plurality of pad patterns 145a may extend from the lower surface of the third semiconductor chip 140 toward the uppermost second semiconductor chip (refer to 120U in FIG. 1) in the vertical direction (Z direction). Each of the plurality of pad patterns 145a may be surrounded by the adhesive layer 130. The plurality of pad patterns 145a may be separated from the uppermost second semiconductor chip (refer to 120U in FIG. 1) with the adhesive layer 130 therebetween in the vertical direction (Z direction).

In one or more embodiments, the plurality of pad patterns 145a may have an inverted dome-shaped cross-section. For example, each of the plurality of pad patterns 145a may have a flat upper surface and a dome-shaped cross-section having a convex lower surface in a direction toward the uppermost second semiconductor chip (refer to 120U in FIG. 1).

In one or more embodiments, a vertical direction height Hula of each of the plurality of pad patterns 145a may be about 3 μm or more and about 4 μm or less. For example, a vertical direction height (Z direction length) of each of the plurality of pad patterns 145a may be about 3.8 μm. In this case, the vertical direction height (Z direction length) of each of the plurality of pad patterns 145a may mean a distance between the upper surface of each of the plurality of pad patterns 145a and a point closest to the uppermost second semiconductor chip (refer to 120U in FIG. 1) (that is, a point at the lowest location in FIG. 3) among the lower surface of each of the plurality of pad patterns 145a.

In one or more embodiments, a separation distance Hs1a in the vertical direction (Z direction) between each of the plurality of pad patterns 145a and the uppermost second semiconductor chip (refer to 120U in FIG. 1) may be about 2 μm or less. For example, the separation distance Hs1a in the vertical direction (Z direction) between each of the plurality of pad patterns 145a and the uppermost second semiconductor chip 120U may be about 0.2 μm.

In one or more embodiments, the plurality of pad patterns 145a may be arranged on the entire area of the lower surface of the third semiconductor chip 140. In one or more embodiments, the sum of the area of each of the plurality of pad patterns 145a on a plane perpendicular to the second horizontal direction (Y direction) may be about 5% to about 30% of the area of the third semiconductor chip 140 on a plane perpendicular to the second horizontal direction (Y direction). In one or more embodiments, each of the plurality of pad patterns 145a may include Ni, Cu, or a combination thereof.

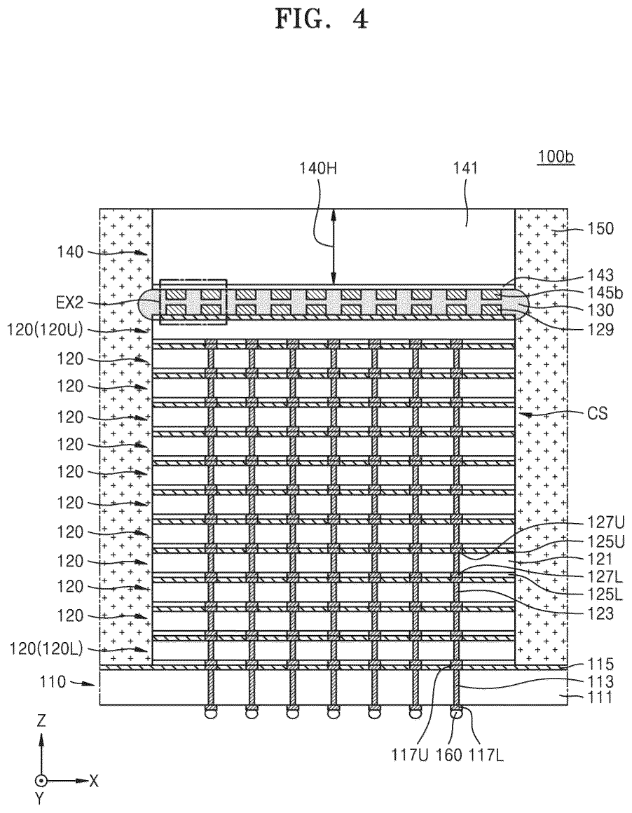

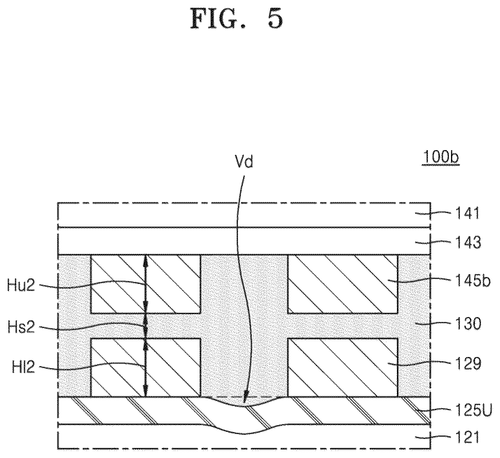

FIG. 4 is a cross-sectional view of a semiconductor package 100b according to an embodiment. FIG. 5 is an enlarged view of region EX2 in FIG. 4. Because components of the semiconductor package 100b illustrated in FIGS. 4 and 5 are similar to components of the semiconductor package 100 illustrated in FIGS. 1 and 2, differences thereof are mainly described below.

Referring to FIGS. 4 and 5, the semiconductor package 100b may include a plurality of first pad patterns 145b arranged under the lower surface of the third semiconductor chip 140, and may include substantially the same components as those of the semiconductor package 100 illustrated in FIGS. 1 and 2 except that a second pad pattern 129 arranged on the upper surface of the uppermost second semiconductor chip 120U is included.

The plurality of pad patterns 145b may be arranged under a lower surface of the third semiconductor chip 140. Each of the plurality of first pad patterns 145b may extend from the lower surface of the third semiconductor chip 140 toward the uppermost second semiconductor chip 120U in the vertical direction (Z direction). Each of the plurality of first pad patterns 145b may be surrounded by the adhesive layer 130.

The plurality of second pad patterns 129 may be arranged on an upper surface of the uppermost second semiconductor chip 120U. Each of the plurality of second pad patterns 129 may extend from the upper surface of the uppermost second semiconductor chip 120U toward the third semiconductor chip 140 in the vertical direction (Z direction). Each of the plurality of second pad patterns 129 may be surrounded by the adhesive layer 130.

The plurality of first pad patterns 145b may overlap the plurality of second pad patterns 129, respectively. A horizontal area of each of the plurality of first pad patterns 145b may be substantially the same as a horizontal area of each of the plurality of second pad patterns 129.

In an embodiment, a sum of a vertical direction height Hu2 of each of the plurality of first pad patterns 145b and a vertical direction height Hl2 of each of the plurality of second pad patterns 129 may be about 3 μm or more, and about 4 μm or less.

In an embodiment, the vertical direction height Hu2 of each of the plurality of first pad patterns 145b and the vertical direction height Hl2 of each of the plurality of second pad patterns 129 may be substantially the same as each other.

In an embodiment, the vertical direction height Hu2 of each of the plurality of first pad patterns 145b and the vertical direction height Hl2 of each of the plurality of second pad patterns 129 may be substantially different from each other.

In one or more embodiments, a separation distance Hs2 between each of the plurality of first pad patterns 145b and each of the plurality of second pad patterns 129 in the vertical direction (Z direction) may be about 2 μm or less. For example, the separation distance Hs2 between each of the plurality of first pad patterns 145b and each of the plurality of second pad patterns 129 in the vertical direction (Z direction) may be about 0.2 μm.

In one or more embodiments, each of the plurality of first pad patterns 145b and each of the plurality of second pad patterns 129 may have a rectangular shape on a cross-section perpendicular to the second horizontal direction (Y direction).

In one or more embodiments, each of the plurality of first pad patterns 145b and each of the plurality of second pad patterns 129 may include Ni, Cu, or a combination thereof. For example, each of the plurality of first pad patterns 145b and each of the plurality of second pad patterns 129 may include Cu.

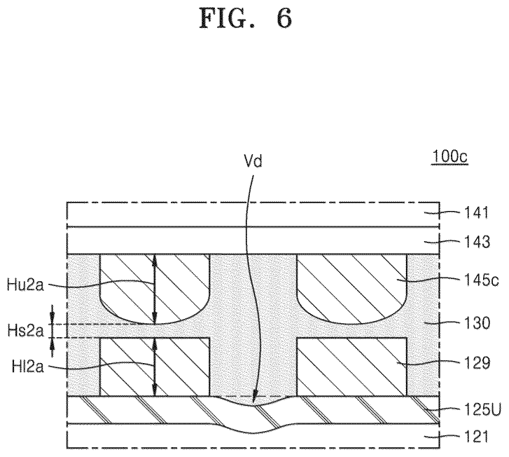

FIG. 6 is an enlarged view of a region corresponding to region EX2 in FIG. 4. FIG. 6 is an enlarged cross-sectional view enlarging a region corresponding to region EX2 in FIG. 4 among cross-sections of a semiconductor package 100c, according to an embodiment. Because components of the semiconductor package 100c illustrated in FIG. 6 are similar to components of the semiconductor package 100b illustrated in FIGS. 4 and 5, differences thereof are mainly described below.

Referring to FIG. 6, the semiconductor package 100c may have substantially the same components as the components of the semiconductor package 100b illustrated in FIGS. 4 and 5, except that the semiconductor package 100c includes a plurality of first pad patterns 145c having an inverted dome-shaped cross-section rather than the rectangular cross-section of the plurality of first pad patterns 145b illustrated in FIGS. 4 and 5.

Each of the plurality of first pad patterns 145c may extend from the lower surface of the third semiconductor chip 140 toward the uppermost second semiconductor chip (refer to 120U in FIG. 4) in the vertical direction (Z direction). Each of the plurality of first pad patterns 145c may be surrounded by the adhesive layer 130. The plurality of first pad patterns 145c may be separated from the uppermost second semiconductor chip (refer to 120U in FIG. 4) with the adhesive layer 130 therebetween in the vertical direction (Z direction).

In one or more embodiments, the plurality of first pad patterns 145c may have an inverted dome-shaped cross-section. For example, each of the plurality of first pad patterns 145c may have a flat upper surface and a convex lower surface in a direction toward the uppermost second semiconductor chip (refer to 120U in FIG. 4).

In an embodiment, a sum of a vertical direction height Hu2a of each of the plurality of first pad patterns 145c and a vertical direction height Hl2a of each of the plurality of second pad patterns 129 may be about 3 μm or more, and about 4 μm or less. In this case, the vertical direction height Hu2a of each of the plurality of first pad patterns 145c may mean a distance between the upper surface of each of the plurality of first pad patterns 145c and a point closest to the uppermost second semiconductor chip (refer to 120U in FIG. 4) (that is, a point at the lowest location in FIG. 6) among the lower surface of each of the plurality of first pad patterns 145c.

In an embodiment, the vertical direction height Hu2a of each of the plurality of first pad patterns 145c and the vertical direction height Hl2a of each of the plurality of second pad patterns 129 may be substantially different from each other.

In one or more embodiments, a separation distance Hs2a between each of the plurality of first pad patterns 145c and each of the plurality of second pad patterns 129 in the vertical direction (Z direction) may be about 2 μm or less. For example, the separation distance Hs2a between each of the plurality of first pad patterns 145c and each of the plurality of second pad patterns 129 in the vertical direction (Z direction) may be about 0.2 μm.

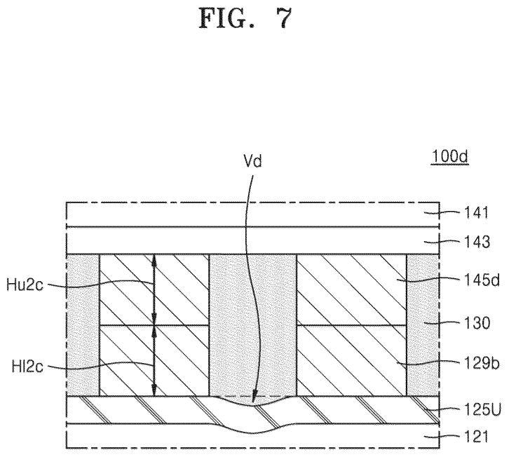

FIG. 7 is an enlarged view of a region corresponding to region EX2 in FIG. 4. FIG. 7 is an enlarged cross-sectional view enlarging a region corresponding to region EX2 in FIG. 4 among cross-sections of a semiconductor package 100d, according to an embodiment. Because components of the semiconductor package 100d illustrated in FIG. 7 are similar to components of the semiconductor package 100b illustrated in FIGS. 4 and 5, differences thereof are mainly described below.

Referring to FIG. 7, the semiconductor package 100d may include substantially the same components as those of the semiconductor package 100b illustrated in FIGS. 4 and 5, except that the semiconductor package 100d includes a plurality of first pad patterns 145d and a plurality of second pad patterns 129b, which are in contact with each other.

The plurality of first pad patterns 145d and the plurality of second pad patterns 129b may be in contact with each other. Accordingly, the plurality of first pad patterns 145b may not be separated from the plurality of second pad patterns 129b in the vertical direction (Z direction).

In an embodiment, a sum of a vertical direction height Hu2c of each of the plurality of first pad patterns 145d and a vertical direction height Hl2c of each of the plurality of second pad patterns 129b may be about 3 μm or more, and about 4 μm or less.

In an embodiment, the vertical direction height Hu2c of each of the plurality of first pad patterns 145d and the vertical direction height Hl2c of each of the plurality of second pad patterns 129b may be substantially the same as each other.

In an embodiment, the vertical direction height Hu2c of each of the plurality of first pad patterns 145c and the vertical direction height Hl2c of each of the plurality of second pad patterns 129b may be substantially different from each other.

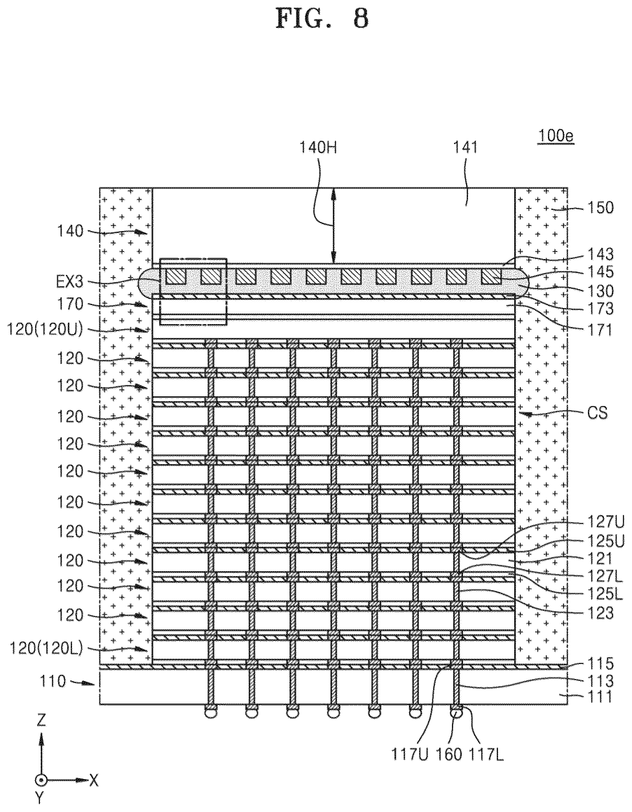

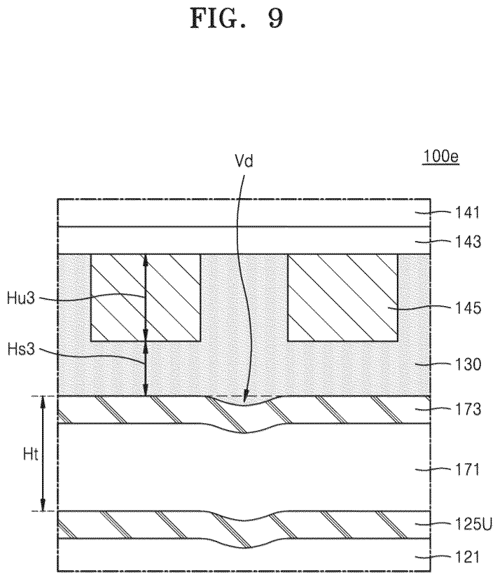

FIG. 8 is a cross-sectional view of a semiconductor package 100e according to an embodiment. FIG. 9 is an enlarged view of a region corresponding to region EX3 in FIG. 8. Because components of the semiconductor package 100e illustrated in FIGS. 8 and 9 are similar to components of the semiconductor package 100 illustrated in FIGS. 1 and 2, differences thereof are mainly described below.

Referring to FIGS. 8 and 9, the semiconductor package 100e may include substantially the same components as those of the semiconductor package 100 illustrated in FIGS. 1 and 2, except that the semiconductor package 100e includes a fourth semiconductor chip 170 arranged between the chip stacked structure CS and the third semiconductor chip 140.

The fourth semiconductor chip 170 may be arranged on the uppermost second semiconductor chip 120U of the chip stacked structure CS. The fourth semiconductor chip 170 and the uppermost second semiconductor chip 120U may be directly bonded to each other by using, for example, an Si—O—Si bonding, etc. In one or more embodiments, the fourth semiconductor chip 170 may include a dummy chip. In one or more embodiments, a horizontal area of the fourth semiconductor chip 170 may be substantially the same as a horizontal area of each of the plurality of second semiconductor chips 120 and a horizontal area of each of the third semiconductor chip 140.

The fourth semiconductor chip 170 may include a fourth semiconductor substrate 171 and a fourth upper insulating layer 173. The fourth semiconductor substrate 171 may include only a semiconductor material such as Si. The fourth upper insulating layer 173 may be arranged on the upper surface of the fourth semiconductor substrate 171. The fourth upper insulating layer 173 may cover a upper surface of the fourth semiconductor substrate 171. The fourth upper insulating layer 173 may include a material substantially the same as or similar to the first upper insulating layer 115.

In one or more embodiments, a vertical direction height Ht of the fourth semiconductor chip 170 may be less than the vertical direction height 140H of the third semiconductor chip 140. For example, the vertical direction height Ht of the fourth semiconductor chip 170 may be about 55 μm, and the vertical direction height 140H of the third semiconductor chip 140 may be about 110 μm.

The fourth semiconductor chip 170 may be separated from the plurality of first pad patterns 145 formed under the lower surface of the third semiconductor chip 140 with the adhesive layer 130 therebetween in the vertical direction (Z direction).

In one or more embodiments, a vertical direction height Hu3 of each of the plurality of first pad patterns 145 may be about 3 μm or more and about 4 μm or less. For example, the vertical direction height Hu3 of each of the plurality of first pad patterns 145 may be about 3 μm.

In one or more embodiments, a separation distance Hs3 in the vertical direction (Z direction) between each of the plurality of first pad patterns 145 and the fourth semiconductor chip 170 may be about 2 μm or less. For example, the separation distance Hs3 in the vertical direction (Z direction) between each of the plurality of first pad patterns 145 and the fourth semiconductor chip 170 may be about 1 μm.

Although the plurality of first pad patterns 145 are illustrated as having a rectangular cross-section in FIGS. 8 and 9, the disclosure is not limited thereto. For example, the plurality of first pad patterns 145 may also include a lower surface having a dome shape as illustrated in FIG. 3.

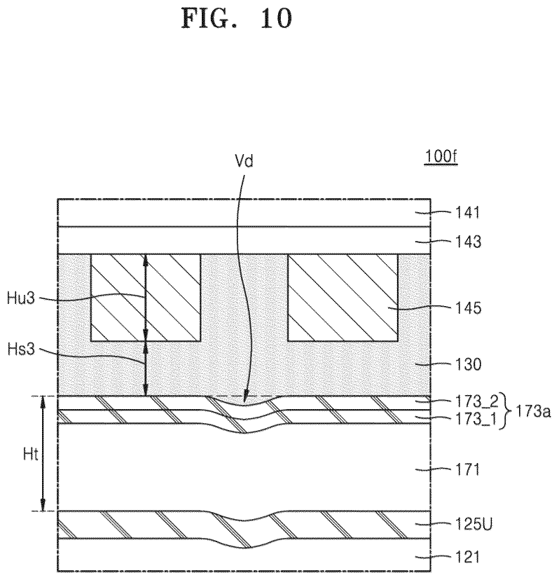

FIG. 10 is an enlarged view of a region corresponding to region EX3 in FIG. 8. FIG. 10 is an enlarged cross-sectional view enlarging a region corresponding to region EX3 in FIG. 8 among cross-sections of a semiconductor package 100f, according to an embodiment. Because components of the semiconductor package 100f illustrated in FIG. 10 are similar to components of the semiconductor package 100e illustrated in FIGS. 8 and 9, differences thereof are mainly described below.

Referring to FIG. 10, the semiconductor package 100f may include substantially the same components as those of the semiconductor package 100e illustrated in FIGS. 8 and 9, except that the semiconductor package 100e includes a fourth upper insulating layer 173a including a plurality of layers.

The fourth upper insulating layer 173a of the semiconductor package 100f may include a first sub upper insulating layer 173_1 and a second sub upper insulating layer 173_2 sequentially stacked on the upper surface of the fourth semiconductor substrate 171.

In one or more embodiments, each of the first sub upper insulating layer 173_1 and the second sub upper insulating layer 173_2 may include an oxide layer or a nitride layer.

In one or more embodiments, the first sub upper insulating layer 173_1 and the second sub upper insulating layer 173_2 may include different materials from each other. For example, the first sub upper insulating layer 173_1 may include silicon oxide, and the second sub upper insulating layer 173_2 may include silicon nitride.

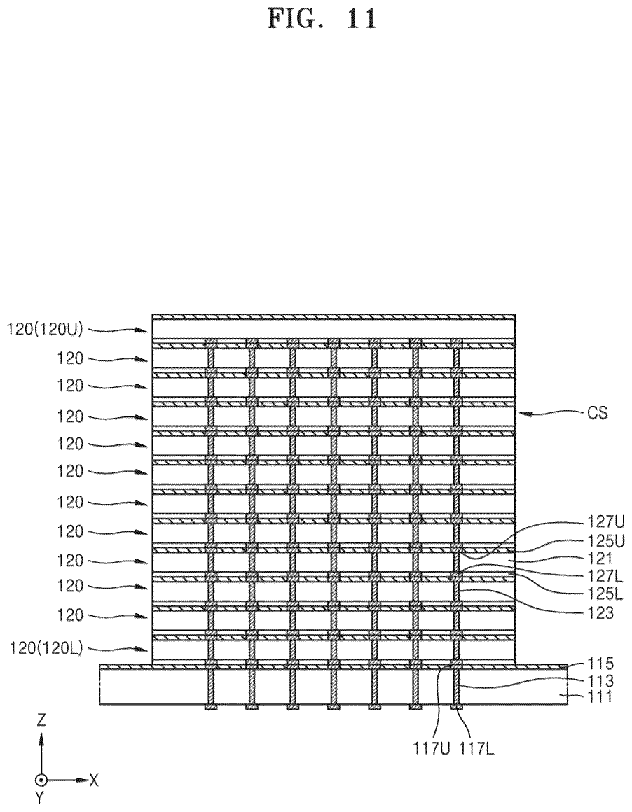

FIGS. 11, 12A, 12B, 13A, 13B, and 14 are cross-sectional views for describing a method of manufacturing the semiconductor package 100, according to embodiments.

Referring to FIG. 11, the chip stacked structure CS may be formed by stacking the plurality of second semiconductor chips 120 on the provided first semiconductor chip 110. Each of the plurality of second semiconductor chips 120 may be bonded to each other by using a metal-metal direct bonding.

Firstly, after the lowermost second semiconductor chip 120L is arranged on the first semiconductor chip 110 so that the second lower pad 127L of the lowermost second semiconductor chip 120L and the first upper pad 117U of the first semiconductor chip 110 are in contact with each other, the lowermost second semiconductor chip 120L and the first semiconductor chip 110 may be connected to each other by applying a metal-metal direct bonding on the second lower pad 127L and the first upper pad 117U by using heat and pressure.

Next, after one second semiconductor chip 120 is arranged on the lowermost second semiconductor chip 120L so that the second lower pad 127L of one second semiconductor chip 120 and the second upper pad 127U of the lowermost second semiconductor chip 120L are in contact with each other, one second semiconductor chip 120 arranged on the lowermost second semiconductor chip 120L may be connected to the lowermost second semiconductor chip 120L, by applying a metal-metal direct bonding on the lowermost second semiconductor chip 120L of the one second semiconductor chip 120 and the second upper pad 127U of the lowermost second semiconductor chip 120L by using heat and pressure.

Thereafter, by repeatedly performing the bonding process described above, the chip stacked structure CS may be formed on the first semiconductor chip 110.

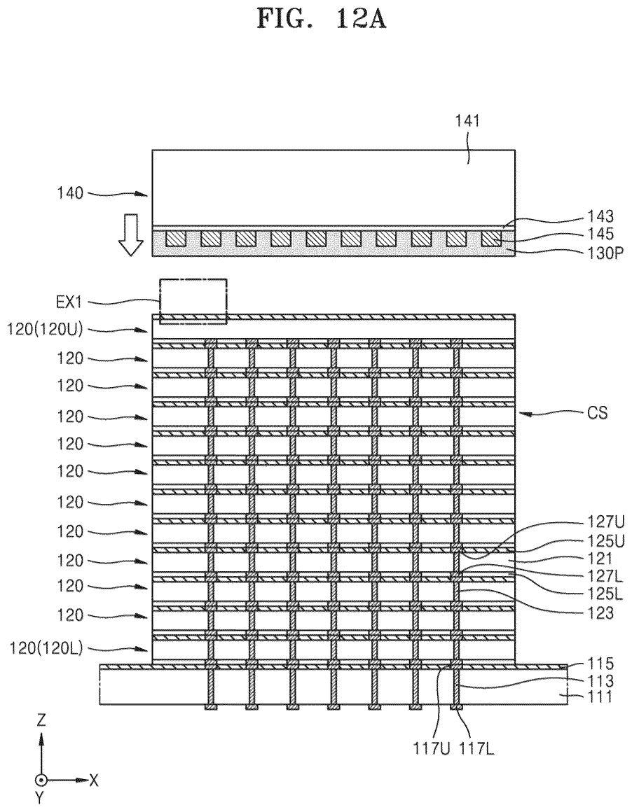

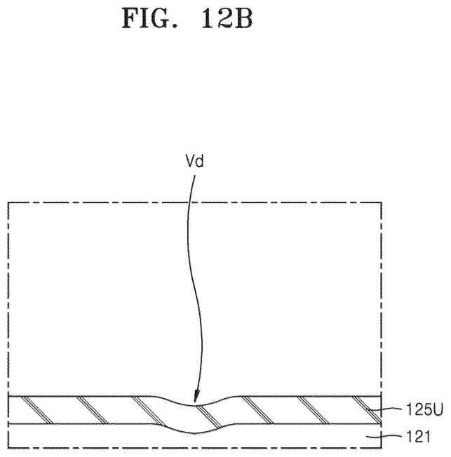

In one or more embodiments, after the chip stacked structure CS is formed, the plurality of second pad patterns 129 of the semiconductor package 100b illustrated in FIGS. 4 and 5 may also be formed on the upper surface of the uppermost second semiconductor chip 120U. In this case, by performing processes to be described below with reference to FIGS. 12A, 12B, 13A, 13B, and 14, the semiconductor package 100b illustrated in FIGS. 4 and 5 may be manufactured, or the semiconductor package 100d illustrated in FIG. 7 may be manufactured.

In other embodiments, after the chip stacked structure CS is formed, the fourth semiconductor chip 170 illustrated in FIGS. 8 and 9 may be arranged on the chip stacked structure CS. In this case, by performing processes to be described below with reference to FIGS. 12A, 12B, 13A, 13B, and 14, the semiconductor package 100e illustrated in FIGS. 8 and 9 may be manufactured, or the semiconductor package 100f illustrated in FIG. 10 may be manufactured.

Referring to FIGS. 12A and 12B, the third semiconductor chip 140 including the plurality of pad patterns 145 formed thereunder may be provided on the chip stacked structure CS. In this case, an adhesive material layer 130P covering the plurality of pad patterns 145 may be formed under the lower surface of the third semiconductor chip 140. The adhesive material layer 130P may include a material substantially the same as or similar to the material of the adhesive layer 130 of the semiconductor package 100 illustrated in FIGS. 1 and 2. Side surfaces of the adhesive material layer 130P may be on the same flat surface as the side surfaces of the third semiconductor chip 140 in the vertical direction (Z direction).

The uppermost second semiconductor chip 120U may include the depression void Vd. In a process of stacking the plurality of second semiconductor chips 120, the depression void Vd may be formed on the upper surface of the uppermost second semiconductor chip 120U to overlap the second wiring layer included in each of the plurality of second semiconductor chips 120 in the vertical direction (Z direction).

In one or more embodiments, the plurality of pad patterns 145 may be formed on the lower surface of the third semiconductor chip 140 to have a rectangular shape, in a cross-section perpendicular to the second horizontal direction (Y direction).

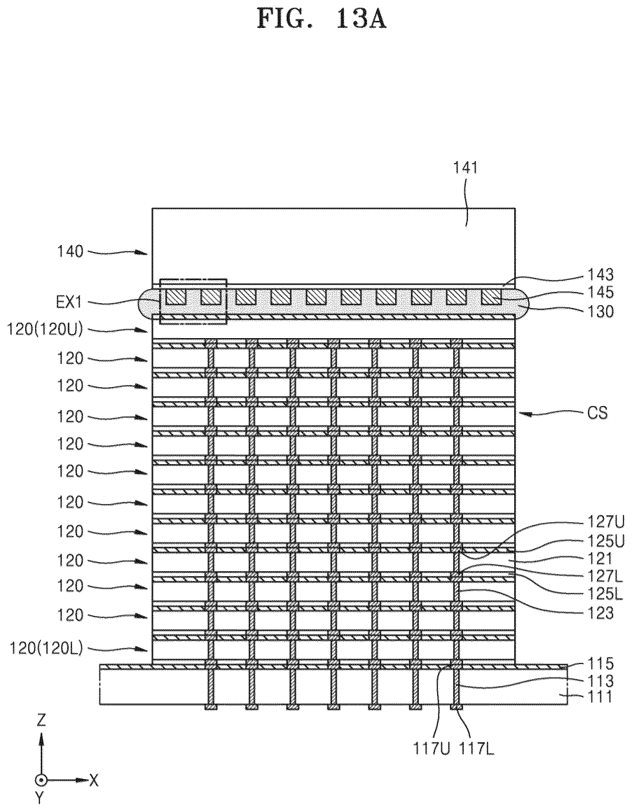

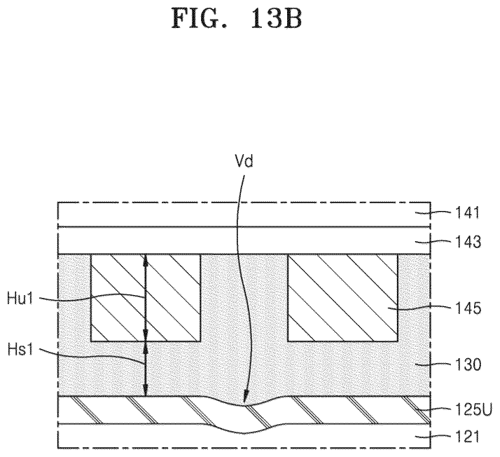

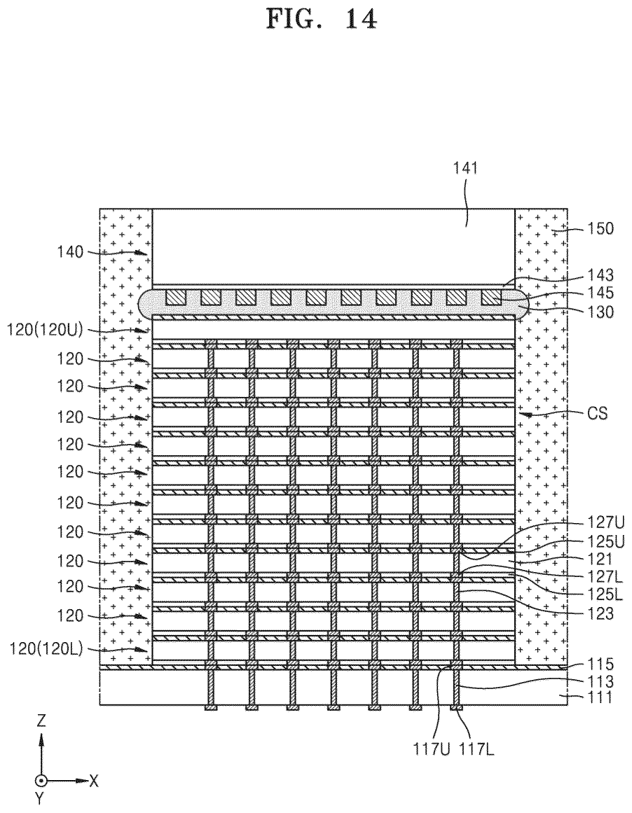

In one or more embodiments, unlike as illustrated in FIGS. 12A and 12B, the plurality of pad patterns 145 may also be formed on the lower surface of the third semiconductor chip 140 to have an inverted dome-shaped cross-section. In this case, by performing processes to be described below with reference to FIGS. 13A, 13B, and 14, the semiconductor package 100a illustrated in FIG. 3 may be manufactured, or the semiconductor package 100c illustrated in FIG. 6 may be manufactured depending on whether the plurality of second pad patterns 129 has been formed.

Referring to FIGS. 13A and 13B, the third semiconductor chip 140 provided on the chip stacked structure CS may be bonded to the chip stacked structure CS. For example, the third semiconductor chip 140 and the chip stacked structure CS may be bonded to each other by using a thermal compression process through the adhesive material layer (refer to 130P in FIG. 12A). In this case, the adhesive material layer 130P, with heat and pressure applied thereto, may be referred to as the adhesive layer 130. By applying the thermal compression process, the adhesive layer 130 may fill the depression void Vd formed on the upper surface of the uppermost second semiconductor chip 120U. In addition, the adhesive layer 130 may protrude from the side surfaces of the third semiconductor chip 140 to the outside as a result of the thermal compression process.

Referring to FIG. 14, the molding layer 150 covering side surfaces of each of the chip stacked structure CS and the third semiconductor chip 140 may be formed. Next, a planarization process may be performed to arrange the upper surface of the molding layer 150 and the upper surface of the third semiconductor chip 140 on the same flat surface. In one or more embodiments, the planarization process may also be omitted. When the planarization process is omitted, the molding layer 150 may also cover the upper surface of the third semiconductor chip 140.

Next, by forming a first connection terminal 160 on the first lower pad 117L of the first semiconductor chip 110, the semiconductor package 100 illustrated in FIGS. 1 and 2 may be formed.

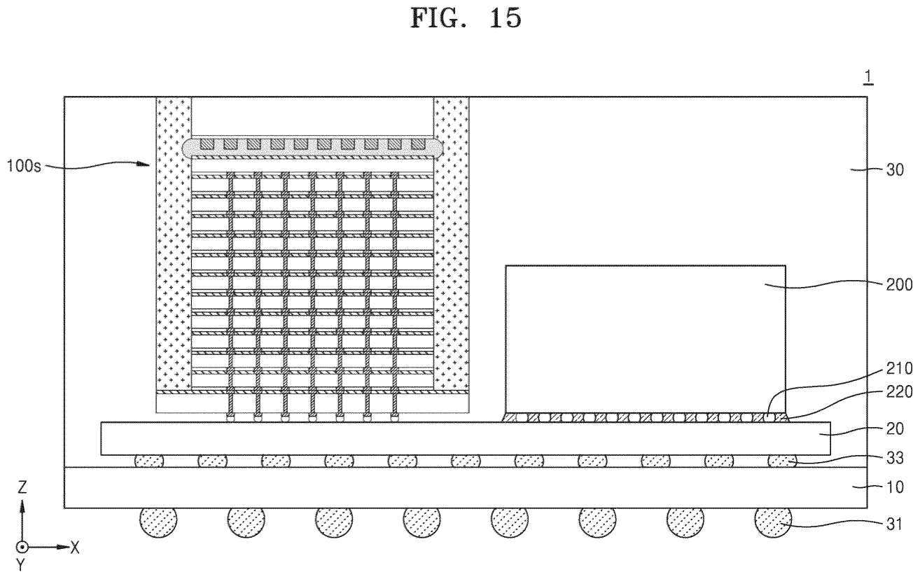

FIG. 15 is a cross-sectional view of a semiconductor package 1 according to an embodiment. The semiconductor package 1 may include a package substrate 10, an interposer substrate 20, a sub semiconductor package 100s, and a sub semiconductor chip 200.

The package substrate 10 may include a printed circuit board. For example, the first package substrate 10 may include a multi-layer printed circuit board.

The package substrate 10 may include a substrate base, and an upper pad and a lower surface pad respectively formed on an upper surface and a lower surface of the substrate base. The substrate base may include a single base layer or may have a structure in which a plurality of base layers are stacked. The substrate base may include at least one of, for example, phenol resin, epoxy resin, and polyimide. The substrate base may include at least one of, for example, frame retardant 4 (FR4), tetrafunctional epoxy, polyphenylene ether, epoxy/polyphenylene oxide, bismaleimide triazine (BT), thermount, cyanate ester, polyimide, and liquid crystal polymer. The upper pad and the lower pad may be exposed by a solder resist layer covering the upper and lower surfaces of the substrate base, respectively.

An external connection terminal 31 may be arranged under the lower pad of the package substrate 10. The external connection terminal 31 may include, for example, a solder ball or a bump. The external connection terminal 31 may electrically connect the semiconductor package 1 to an external device.

The interposer substrate 20 may be arranged on the package substrate 10. The interposer substrate 20 may include a substrate base including a semiconductor material, and an upper pad and a lower surface pad respectively formed on an upper surface and a lower surface of the substrate base. The substrate base may include, for example, a silicon wafer or a glass substrate. Internal wirings may be formed on an upper surface, a lower surface, and/or on the inside of the substrate base. In addition, through vias electrically connecting the upper pad to the lower pad may be formed inside the substrate base. The interposer substrate 20 may be installed on the package substrate 10 by using connection terminals 33. The connection terminal 33 may include, for example, a solder ball or a bump.

The sub semiconductor package 100s and the sub semiconductor chip 200 may be arranged on the interposer substrate 20. On the interposer substrate 20, the sub semiconductor package 100s and the sub semiconductor chip 200 may be arranged apart from each other in the vertical direction (Z direction).

The sub semiconductor package 100s may be substantially the same as at least one of the semiconductor packages 100, 100a, 100b, 100c, 100d, 100e, and 100f described with reference to FIGS. 1 through 10.

The sub semiconductor chip 200 may be attached onto the interposer substrate 20 so that an active surface of the sub semiconductor chip 200 faces the interposer substrate 20. The second semiconductor chip may include a processor unit. For example, the second semiconductor chip may include a micro processing unit (MPU) or a graphics processing unit (GPU). The semiconductor substrate constituting the sub-semiconductor chip 200 may include, for example, a semiconductor element, such as Si and Ge, and at least one compound semiconductor, such as SiGe, SiC, GaAs, InAs, and InP. The semiconductor substrate may include a conductive region, for example, a well doped with an impurity, or a structure doped with an impurity. The semiconductor substrate may have various element isolation structures such as a shallow trench isolation (STI) structure. The semiconductor substrate may include an active surface and an inactive surface opposite to the active surface. A semiconductor device including a plurality of individual devices of various types may be formed on the active surface of the semiconductor substrate. The plurality of individual devices may include various microelectronic devices, for example, a metal-oxide-semiconductor field effect transistor (MOSFET) such as a complementary metal-insulator-semiconductor (CMOS) transistor, an image sensor such as a system large scale integration (LSI), and CMOS imaging sensor (CIS), a micro-electro-mechanical system (MEMS), an active device, a passive device, etc. The plurality of individual devices may be electrically connected to the conductive region of a semiconductor substrate. The semiconductor device may further include at least two of the plurality of individual devices, or a conductive distribution or a conductive plug electrically connecting the plurality of individual devices to the conductive region of the semiconductor substrate. In addition, each of the plurality of individual devices may be electrically isolated from another adjacent individual devices by an insulating layer.

The sub semiconductor chip 200 may be electrically connected to the interposer substrate 20 via a first connection terminal 210 arranged on the active surface. The first connection terminal 210 may include, for example, a solder ball or a bump.

A first underfill material layer 220 may be formed between the sub semiconductor chip 200 and the interposer substrate 20. The first underfill material layer 220 may fill a space between the sub semiconductor chip 200 and the interposer substrate 20. The first underfill material layer 220 may include, for example, epoxy resin. The first underfill material layer 220 may also include a portion of a first molding layer 30 formed by using a moldable underfill (MUF) method.

The first molding layer 30 may be arranged on the package substrate 10. The first molding layer 30 may surround side surfaces of each of the sub semiconductor package 100s and the sub semiconductor chip 200. The first molding layer 30 may include, for example, epoxy molding compound (EMC). The first molding layer 30 may be formed independently from the molding layer (refer to 150 in FIG. 1) of the sub semiconductor package 100s. In one or more embodiments, as illustrated in FIG. 15, the first molding layer 30 may not cover the upper surface of the sub semiconductor package 100s. In other embodiments, unlike as illustrated in FIG. 15, the first molding layer 30 may not cover the upper surface of the sub semiconductor package 100s. For example, the first molding layer 30 may not cover the upper surface of the third semiconductor chip (refer to 140 in FIG. 1) of the sub semiconductor package 100s.

Although it is illustrated in FIG. 15 that the upper surface of the sub semiconductor chip 200 is not horizontally on the same plane as the upper surface of the sub semiconductor package 100s, the embodiment is not limited thereto. For example, the upper surface of the sub semiconductor chip 200 may be horizontally on the same flat surface as the upper surface of the sub semiconductor package 100s. In this case, the upper surface of the third semiconductor chip 140 of the sub semiconductor package 100s and the upper surface of the sub semiconductor chip 200 may be exposed from the first molding layer 30.

While the disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor chip;
a chip stacked structure on the first semiconductor chip, the chip stacked structure comprising a plurality of second semiconductor chips;
a third semiconductor chip on the chip stacked structure;
an adhesive layer between the chip stacked structure and the third semiconductor chip; and
a first pad pattern on a lower surface of the third semiconductor chip,
wherein the adhesive layer surrounds the first pad pattern and the adhesive layer is between the first pad pattern and the chip stacked structure.

2. The semiconductor package of claim 1, wherein a height of the first pad pattern in a vertical direction is about 3 μm or more and about 4 μm or less.

3. The semiconductor package of claim 1, wherein a separation distance between the first pad pattern and the chip stacked structure is about 2 μm or less.

4. The semiconductor package of claim 1, wherein an area of the first pad pattern is about 5% to about 30% of an area of the third semiconductor chip.

5. The semiconductor package of claim 1, wherein an upper surface of an uppermost second semiconductor chip among the plurality of second semiconductor chips comprises a depression void, and the depression void is filled with the adhesive layer.

6. The semiconductor package of claim 1, wherein the first pad pattern comprises a rectangular-shaped cross section.

7. The semiconductor package of claim 1, wherein the first pad pattern comprises an inverted-dome-shaped cross section.

8. The semiconductor package of claim 1, further comprising:
a second pad pattern on an upper surface of an uppermost second semiconductor chip among the plurality of second semiconductor chips, wherein the second pad pattern overlaps the first pad pattern in a vertical direction.

9. The semiconductor package of claim 8, wherein the adhesive layer is between the second pad pattern and the first pad pattern.

10. The semiconductor package of claim 8, wherein the second pad pattern is in contact with the first pad pattern.

11. The semiconductor package of claim 8, wherein each of the first pad pattern and the second pad pattern comprises a rectangular-shaped cross section or an inverted-dome-shaped cross section.

12. The semiconductor package of claim 1, further comprising:
a fourth semiconductor chip between the adhesive layer and the chip stacked structure,
wherein the adhesive layer is between the first pad pattern and the fourth semiconductor chip.

13. The semiconductor package of claim 12, wherein the fourth semiconductor chip comprises a dummy chip.

14. A semiconductor package comprising:
a package substrate;
an interposer substrate on the package substrate;
a sub semiconductor package on the interposer substrate; and
a semiconductor chip on the interposer substrate,
wherein the semiconductor chip is spaced apart from the sub semiconductor package in a horizontal direction,
wherein the sub semiconductor package comprises:
a first semiconductor chip;
a chip stacked structure on the first semiconductor chip, the chip stacked structure comprising a plurality of second semiconductor chips;
a third semiconductor chip on the chip stacked structure;
an adhesive layer between the chip stacked structure and the third semiconductor chip; and
a first pad pattern on a lower surface of the third semiconductor chip, and
wherein the adhesive layer surrounds the first pad pattern and the adhesive layer is between the first pad pattern and the chip stacked structure.

15. The semiconductor package of claim 14, wherein a height of the first pad pattern in a vertical direction is about 3 μm or more and about 4 μm or less, and a separation distance between the first pad pattern and the chip stacked structure is about 2 μm or less.

16. The semiconductor package of claim 14, wherein the first pad pattern comprises a rectangular-shaped cross section or an inverted-dome-shaped cross section.

17. The semiconductor package of claim 14, further comprising:
a second pad pattern on an upper surface of an uppermost second semiconductor chip among the plurality of second semiconductor chips, wherein the second pad pattern overlaps the first pad pattern in a vertical direction.

18. The semiconductor package of claim 14, further comprising:
a fourth semiconductor chip between the adhesive layer and the chip stacked structure,
wherein the adhesive layer is between the first pad pattern and the fourth semiconductor chip.

19. A semiconductor package comprising:
a first semiconductor chip;
a chip stacked structure on the first semiconductor chip, the chip stacked structure comprising a plurality of second semiconductor chips bonded to each other by metal-metal bonding;
a third semiconductor chip on the chip stacked structure, the third semiconductor chip comprising a dummy chip;
an adhesive layer between the chip stacked structure and the third semiconductor chip, wherein the adhesive layer protrudes from a side surface of the third semiconductor chip to an outside;
a molding layer covering the side surface of the third semiconductor chip and a side surface of each of the chip stacked structure and the adhesive layer; and
a first pad pattern on a lower surface of the third semiconductor chip,
wherein an upper surface of an uppermost second semiconductor chip among the plurality of second semiconductor chips comprises a depression void filled by the adhesive layer,
wherein the adhesive layer surrounds the first pad pattern and the adhesive layer is between the first pad pattern and the chip stacked structure, and
wherein the first pad pattern overlaps the chip stacked structure in a vertical direction.

20. The semiconductor package of claim 19, wherein the first pad pattern comprises Cu, Ni, or a combination thereof.
